(19) United States
(12) Patent Application Publication
(10) Pub. No.: US 2026/0147144 A1
(43) Pub. Date: May 28, 2026

(54) ELECTRONIC DEVICE

(71) Applicant: CARUX TECHNOLOGY PTE. LTD., APERIA (SG)

(72) Inventors: Bo-Tsuen CHEN, Tainan (Tainan Science Park) (TW); Chih-Chang CHEN, Tainan (Tainan Science Park) (TW)

(21) Appl. No.: 19/377,344

(22) Filed: Nov. 3, 2025

(30) Foreign Application Priority Data
Nov. 25, 2024 (CN) 202411694697.7

(51) Int. Cl. G02B 5/02; G02B 5/04; G02B 5/20; H10F 39/00; H10H 29/855; H10K 59/80

(52) U.S. Cl. CPC G02B 5/0215; G02B 5/045; G02B 5/201; H10F 39/806; H10H 29/855; H10K 59/875

(57) ABSTRACT

An electronic device is provided. The electronic device includes an electronic unit and a circuit structure. The circuit structure is electrically connected to the electronic unit. The circuit structure includes a first conductive layer, a first insulating layer and a first heat dissipation element. The first insulating layer is disposed between the first conductive layer and the electronic unit. The first heat dissipation element is in contact with the first conductive layer. Moreover, a heat transfer coefficient of the first dissipation element is greater than a heat transfer coefficient of the first insulating layer and less than a heat transfer coefficient of the first conductive layer.

### CROSS REFERENCE TO RELATED APPLICATIONS

This application claims the benefit of China Application No. 202411694697.7, filed Nov. 25, 2024, the entirety of which is incorporated by reference herein.

### BACKGROUND

### Technical Field

The present disclosure is related to an electronic device, and in particular it is related to an electronic device including functional optical films.

### Description of the Related Art

Electronic products including display panels or sensor components, such as smartphones, tablet computers, laptops, monitors and televisions, have become indispensable necessities in modern society. With the flourishing development of such electronic products, consumers have high expectations for the quality, function or price of these products.

Electronic devices are often equipped with functional optical films to achieve ideal optical effects. Among them, privacy filters and prism sheets can manipulate the direction and angular range of emitted light, and are often used to control the viewing angle of electronic devices (e.g., the light emission angle). However, privacy filters block a significant amount of light, resulting in reduced brightness and light output efficiency of electronic devices, while prism sheets still suffer from stray light issues at wide viewing angles.

As mentioned above, functional optical films commonly used to control viewing angles have not yet met expectations in all aspects. Therefore, improving the performance of functional optical films and thus improving the quality of electronic devices is still one of the current research topics in the industry.

### SUMMARY

In some embodiments of the present disclosure, an electronic device is provided. The electronic device includes a light-emitting structure and an optical film. The optical film is disposed on the light-emitting structure. The optical film includes a microstructure layer and a barrier structure. The barrier structure is adjacent to the microstructure layer. Furthermore, the microstructure layer is disposed between the light-emitting structure and the barrier structure.

In accordance with some other embodiments of the present disclosure, an electronic device is provided. The electronic device includes a sensing structure and an optical film. The optical film is disposed on the sensing structure. The optical film includes a microstructure layer and a barrier structure. The barrier structure is adjacent to the microstructure layer. Furthermore, the microstructure layer is disposed between the sensing structure and the microstructure layer.

### BRIEF DESCRIPTION OF THE DRAWINGS

FIG. 1A is a cross-sectional diagram of an electronic device in some embodiments of the present disclosure;

FIG. 1B is a partially enlarged diagram of area A1 in FIG. 1A in some embodiments of the present disclosure;

FIG. 1C is a partially enlarged diagram of area A2 in FIG. 1A in some embodiments of the present disclosure;

FIG. 2 and FIG. 3 are optical analysis results of an electronic device in some embodiments of the present disclosure;

in some embodiments FIGS. 4 to 8 are cross-sectional diagrams of an electronic device in some embodiments of the present disclosure.

### DETAILED DESCRIPTION

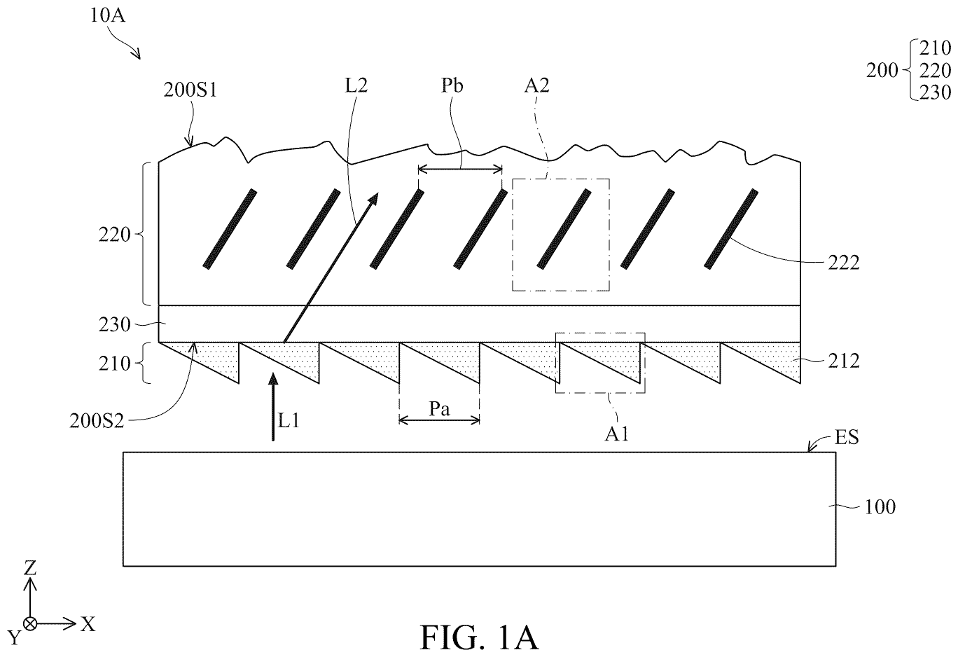

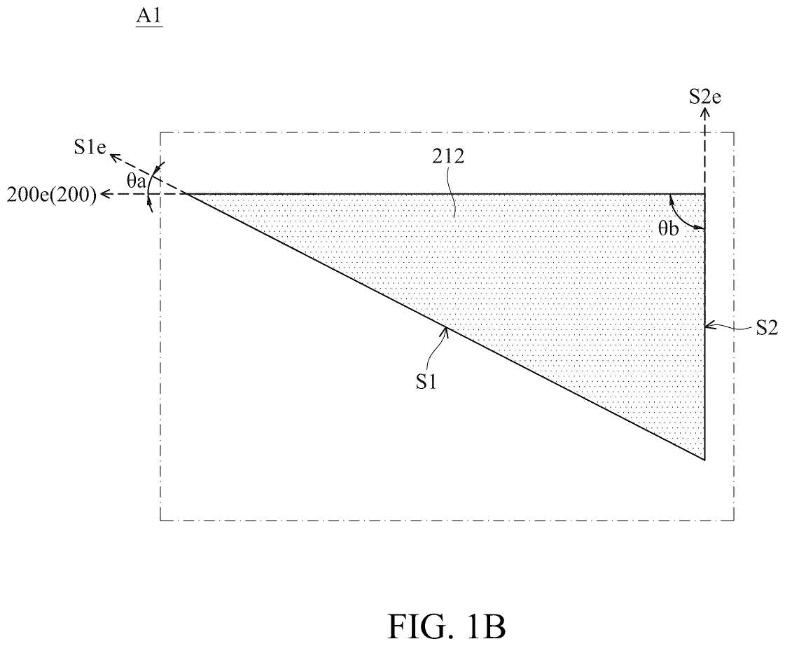

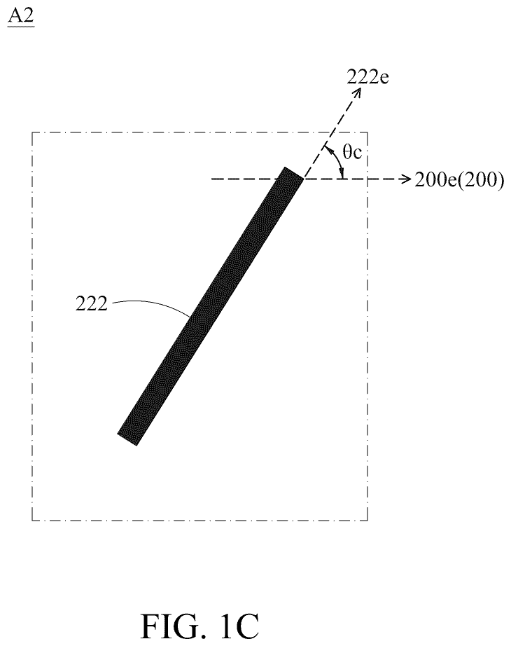

Please refer to FIG. 1, which is a cross-sectional diagram of an electronic device 10A in some embodiments of the present disclosure. As shown in FIG. 1, the electronic device 10A may include a light-emitting structure 100 and an optical film 200, and the optical film 200 is disposed on the light-emitting structure 100. The optical film 200 may be disposed on the side of the light-emitting surface ES of the light-emitting structure 100. The optical film 200 may be integrated with the light-emitting structure 100, for example, by a fixing element. The optical film 200 may be in contact with the light-emitting structure 100, but the present disclosure is not limited thereto.

The light-emitting structure 100 may include a self-luminous structure or a non-self-luminous structure. As shown in FIG. 1A, in an embodiment in which the light-emitting structure 100 is a self-luminous structure, the light-emitting structure 100 may include an organic light-emitting diode (OLED), a mini light-emitting diode (mini LED), a micro LED, or a quantum dot light-emitting diode (quantum dot LED), but the present disclosure is not limited thereto.

The optical film 200 may include a microstructure layer 210 and a barrier structure 220, and the barrier structure 220 is adjacent to the microstructure layer 210. Furthermore, the microstructure layer 210 is disposed between the light-emitting structure 100 and the barrier structure 220. The optical film 200 may be used to adjust the characteristics of the light generated from the light-emitting structure 100. For example, a light L1 generated by the light-emitting structure 100 may be adjusted to a light L2 having a specific optical property (e.g., having a specific light-emitting angle or path) through the optical film 200. In detail, the light L1 generated by the light-emitting structure 100 may first pass through the microstructure layer 210 and then pass through the barrier structure 220. As shown in FIG. 1A, the microstructure layer 210 may be adjacent to the light-emitting surface ES of the light-emitting structure 100, and the barrier structure 220 may be farther from the light-emitting surface ES of the light-emitting structure 100 than the microstructure layer 210.

Please refer to FIG. 1A and FIG. 1B at the same time. FIG. 1B is a partially enlarged diagram of area A1 in FIG. 1A in some embodiments of the present disclosure. The microstructure layer 210 may include a prism 212. For example, the microstructure layer 210 may include a plurality of prisms 212 arranged adjacent to each other. In the cross-sectional view, the prism 212 may have a protruding structure. In some embodiments, the prism 212 has a first sidewall S1 and a second sidewall S2, an angle θa is formed between an extending direction S1e of the first sidewall S1 and an extending direction 200e of the optical film 200, and an angle θb is formed between an extending direction S2e of the second sidewall S2 and an extending direction 200e of the optical film 200. Moreover, the angle θa is different from the angle θb. In other words, the prisms 212 have an asymmetric structure. In detail, the first sidewall S1 of the prism 212 may be connected to the second sidewall S2. In some embodiments, the angle θa and the angle θb may also be the bottom angles of the prism 212 on the side close to the barrier structure 220. In some embodiments, the angle θa may be between 10 degrees and 90 degrees (i.e. 10 degrees ≤angle θa ≤90 degrees), for example, 15, 20, 25, 30, 35, 40, 45, 50, 55, 60, 65, 70, 75, 80 or 85 degrees. In some embodiments, the angle θb may be between 10 degrees and 90 degrees (i.e. 10 degrees≤angle θb≤90 degrees), for example, 15, 20, 25, 30, 35, 40, 45, 50, 55, 60, 65, 70, 75, 80 or 85 degrees. The angle may be measured by an optical microscope (OM), a scanning electron microscope (SEM), a transmission electron microscope (TEM) or other applicable methods.

In addition, in some embodiments, in the microstructure layer 210, the angles θa of the plurality of prisms 212 located at different positions may be different. For example, the difference in the angles θa of the plurality of prisms 212 located at different positions may be between 1 degree and 10 degrees, for example, 2, 3, 4, 5, 6, 7, 8 or 9 degrees.

In some embodiments, there is a pitch Pa between the prisms 212. The pitch Pa of the prisms 212 may be between 10 μm and 100 μm (i.e. 10 μm≤pitch Pa≤100 μm), for example, 20 μm, 30 μm, 40 μm, 50 μm, 60 μm, 70 μm, 80 μm, or 90 μm. In some embodiments, the pitch Pa refers to the distance between one prism 212 and the next adjacent (closest) prism 212 in a direction parallel to the longitudinal direction of the optical film 200 (e.g., the X direction in the figure), and the distance may be the distance between the center points of the prisms 212. According to other embodiments, the pitch Pa may be the distance between a point (e.g., the highest point) of the prism 212 and a point (e.g., the highest point) at a corresponding position of the adjacent prism 212. Furthermore, in the microstructure layer 210, the distance between the prism 212 closest to the edge (not illustrated) of the optical film 200 and the edge of the optical film 200 may be between 10 μm and 1000 μm, for example, between 100 μm and 900 μm, or between 200 μm and 800 μm, such as 300 μm, 400 μm, 500 μm, 600 μm, or 700 μm. In accordance with some embodiments, the pitch and distance can be measured by optical microscope (OM), scanning electron microscope (SEM), transmission electron microscope (TEM) or other applicable methods.

In some embodiments, the extending direction 200e of the optical film 200 refers to a direction parallel to the longitudinal direction of the optical film 200 (for example, the X direction in the figure), and can also be, for example, a direction parallel to the longitudinal direction of the microstructure layer 210, or a direction parallel to the longitudinal direction of the barrier structure 220. It should be understood that, the term “longitudinal direction” can be defined as a direction along or parallel to the long axis of an object. The long axis is defined as a straight line extending lengthwise through the center of an object. For an elongated or elliptical object, the long axis is closest to its maximum longitudinal dimension. For an object without a clear long axis, the long axis can represent the long axis of the smallest rectangle that can surround the object.

In some embodiments, the material of the microstructure layer 210 (prisms 212) may include polycarbonate (PC), polyimide (PI), polyethylene terephthalate (PET), polyether polyol (POP), polymethylmethacrylate (PMMA), cycloolefin polymer (COP), rubber, glass, another suitable material or a combination thereof, but it is not limited thereto. In some embodiments, the material of the microstructure layer 210 may include photocurable adhesive, thermal curable adhesive, photothermal curable adhesive, moisture curable adhesive, another suitable material or a combination thereof, but it is not limited thereto. In some embodiments, the material of the microstructure layer 210 may include optical clear adhesive (OCA), optical clear resin (OCR), acrylic resin, another suitable material or a combination thereof, but it is not limited thereto.

Furthermore, the barrier structure 220 may include a barrier wall 222. For example, the barrier structure 220 may include a plurality of barrier walls 222 arranged adjacent to each other. In detail, the barrier structure 220 may include two substrates (not illustrated) disposed opposite to each other and the barrier walls 222 disposed between the two substrates, and the barrier walls 222 may form a grating. Please refer to FIG. 1A and FIG. 1C at the same time. FIG. 1C is a partially enlarged diagram of area A2 in FIG. 1A in some embodiments of the present disclosure. In some embodiments, an angle θc is formed between an extending direction 222e of the barrier wall 222 and the extending direction 200e of the optical film 200, and the angle θc is greater than 0 degree and less than or equal to 80 degrees (i.e. 0 degree<angle θc≤80 degrees), for example, 5, 10, 15, 20, 25, 30, 35, 40, 45, 50, 55, 60, 65, 70 or 75 degrees.

In some embodiments, there is a pitch Pb between the barrier walls 222. The pitch Pb of the barrier walls 222 may be between 10 μm and 100 μm (i.e. 10 μm≤pitch Pb≤100 μm), for example, 20, 30, 40, 50, 60, 70, 80 or 90 μm. In some embodiments, the pitch Pb refers to the distance between the barrier wall 222 and the next adjacent (closest) barrier wall 222 in a direction parallel to the longitudinal direction of the optical film 200 (e.g., the X direction in the figure), and the distance may be the distance between the center points of the barrier walls 222. According to other embodiments, the pitch Pb may be the distance between a point (e.g., the highest point) of the barrier wall 222 and a point (e.g., the highest point) at a corresponding position of the adjacent barrier wall 222. The pitch Pb between the barrier walls 222 may be the same as or different from the pitch Pa between the prisms 212. Furthermore, as shown in FIG. 1A, in some embodiments, one barrier wall 222 of the barrier structure 220 may be disposed corresponding to one prism 212 of the microstructure layer 210, that is, the barrier walls 222 and the prisms 212 may be arranged in a one-to-one manner, but the present disclosure is not limited thereto. In some embodiments, the barrier walls 222 and the prisms 212 are disposed correspondingly, which means that the barrier walls 222 and the prisms 212 at least partially overlap in a direction perpendicular to the longitudinal direction of the optical film 200 (e.g., the Z direction in the figure).

Furthermore, in some embodiments, in the barrier structure 220, the distance between the barrier wall 222 closest to the edge (not illustrated) of the optical film 200 and the edge of the optical film 200 may be between 10 μm and 1000 μm, for example, between 100 μm and 900 μm, or between 200 μm and 800 μm, for example, 300 μm, 400 μm, 500 μm, 600 μm, or 700 μm.

The barrier walls 222 of the barrier structure 220 may include an opaque material. The barrier walls 222 of the barrier structure 220 may include ink material (e.g., black ink or other suitable color ink), photoresist material (e.g., black photoresist or other suitable color photoresist), resin material (e.g., black resin or other suitable color resin), black metal material, graphene or another suitable opaque material, or a combination thereof, but it is not limited thereto. In the embodiment where the barrier structure 220 includes two substrates (not illustrated) disposed opposite to each other and the barrier walls 222 disposed between the two substrates, the material of the substrate may include polycarbonate (PC), polyimide (PI), polyethylene terephthalate (PET), polyether polyol (POP), polymethylmethacrylate (PMMA), cycloolefin polymer (COP), rubber, glass, another suitable material, or a combination thereof, but it is not limited thereto. In particular, when the material of the barrier walls 222 includes graphene, the thermal conductivity of the barrier structure 220 can be increased, further improving the performance of the electronic device.

As shown in FIG. 1A, the optical film 200 has a first surface 200S1 away from the light-emitting structure 100 and a second surface 200S2 adjacent to the light-emitting structure 100. In some embodiments, the microstructure layer 210 is disposed on the second surface 200S2 of the optical film 200. In some embodiments, the first surface 200S1 of the optical film 200 may be roughened by a surface treatment. For example, a coating may be formed on the first surface 200S1, or the first surface 200S1 may be roughened by a laser roughening process, a chemical etching process, a mechanical grinding process, another suitable process or a combination thereof. In some embodiments, the roughness (Ra) of the first surface 200S1 of the optical film 200 may be between 0.1 μm and 10 μm (i.e. 0.1 micrometer≤roughness≤10 μm), for example, 0.5, 1, 1.5, 2, 2.5, 3, 3.5, 4, 4.5, 5, 5.5, 6, 6.5, 7, 7.5, 8, 8.5, 9 or 9.5 μm. When the first surface 200S1 of the optical film 200 has a specific roughness (e.g., 0.1 micrometer≤roughness≤10 μm), the interference fringe phenomenon that may be caused by the microstructure layer 210 (the prisms 212) can be reduced.

In some embodiments, the roughness may be determined by, for example, using a scanning electron microscope (SEM), a transmission electron microscope (TEM) or a confocal microscope to observe the surface undulations at an appropriate magnification. Moreover, the surface undulations are compared at a unit length (e.g., 50 μm). Herein, “appropriate magnification” means that at least 10 undulating peaks and valleys can be observed on at least one surface under the field of view of this magnification.

In addition, the optical film 200 may further include a light adjustment layer 230, and the light adjustment layer 230 may be disposed between the microstructure layer 210 and the barrier structure 220. The light adjustment layer 230 may include a diffusion film, a brightness enhancement film, a dual brightness enhancement film (DBEF), another optical film with similar functions, or a combination thereof, but it is not limited thereto.

It is worth noting that the optical film 200 with the above-mentioned specific configuration can effectively control the angular range of emitted light of the electronic device and reduce stray light, thereby improving the light-emitting efficiency. In particular, when such an optical film structure is applied to an automotive device, the accurate light projection angle and position enable the driver to view the correct image without being affected by erroneous images or stray light. Furthermore, the aforementioned optical film structure may be applied to a driver display, a passenger display, a center information display (CID), a head-up display (HUD), and the like. The optical film structure may be designed to provide a suitable angle of emitted light for each display, thereby preventing interference among images displayed on different screens.

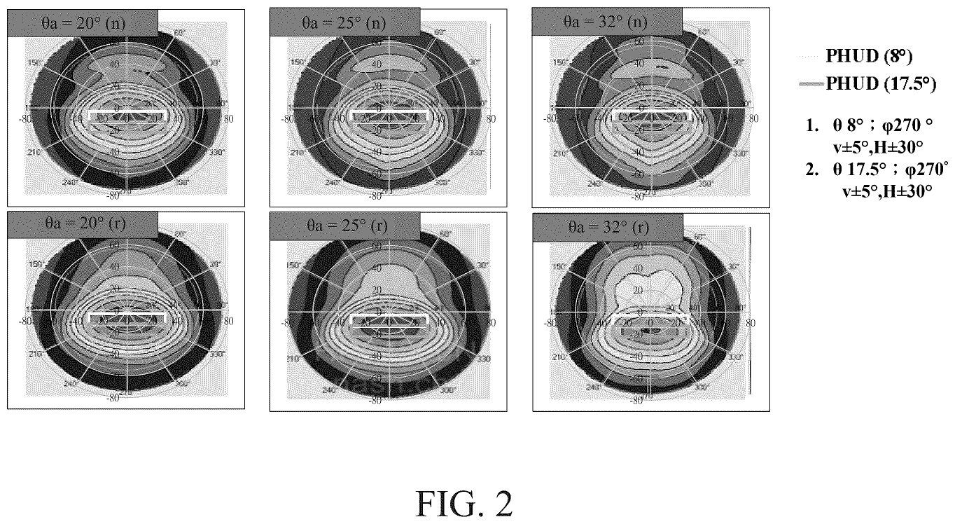

Please refer to FIG. 2, which is an optical analysis result of the electronic device in some embodiments of the present disclosure. This optical analysis result can be obtained by measuring with a conoscopic lens, but it is not limited thereto. For example, the optical analysis result can be measured or analyzed using a Conoscope, BM5A, Conometer80U or another suitable instrument, but it is not limited thereto. In FIG. 2, θa=20 degrees (n), θa=25 degrees (n), and θa=32 degrees (n) respectively show the brightness (cd/m²) distribution diagram when the optical film 200 does not have a barrier structure 220 and the microstructure layer 210 is disposed away from the light-emitting structure 100, and the angle θa of the prism 212 is 20 degrees, 25 degrees, and 32 degrees, and the angle θb is 90 degrees. Furthermore, θa=20 degrees (r), θa=25 degrees (r), and θa=32 degrees (r) respectively show the brightness (cd/m2) distribution diagram when the optical film 200 does not have a barrier structure 220 and the microstructure layer 210 is disposed close to the light-emitting structure 100, and the angle θa of the prism 212 is 20 degrees, 25 degrees, and 32 degrees, and the angle θb is 90 degrees.

As shown in FIG. 2, when the microstructure layer 210 of the optical film 200 has an asymmetric prism 212, a light output shifting effect can be achieved, thereby altering the direction of the light output viewing angle. Moreover, when the prism 212 is adjacent to (facing towards) the light-emitting structure 100 or away from (facing away from) the light-emitting structure 100, the viewing angle shifting effect can be achieved realized. However, since the optical film 200 does not include the barrier structure 220, a relatively large amount of stray light may be produced. Moreover, as shown in FIG. 2, it can be seen that the desired light output angle can be designed by adjusting the angle θa and angle θb of the prism 212, thereby meeting different specification requirements.

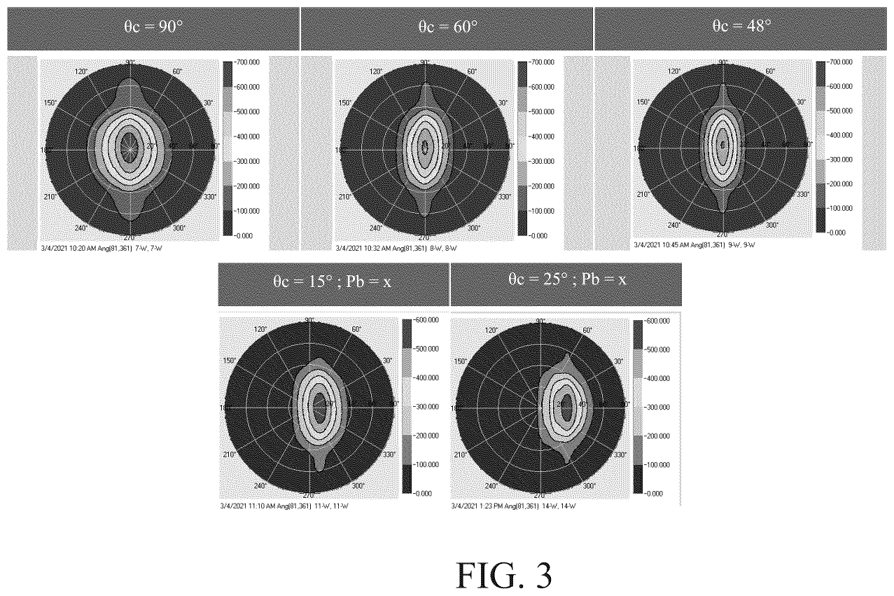

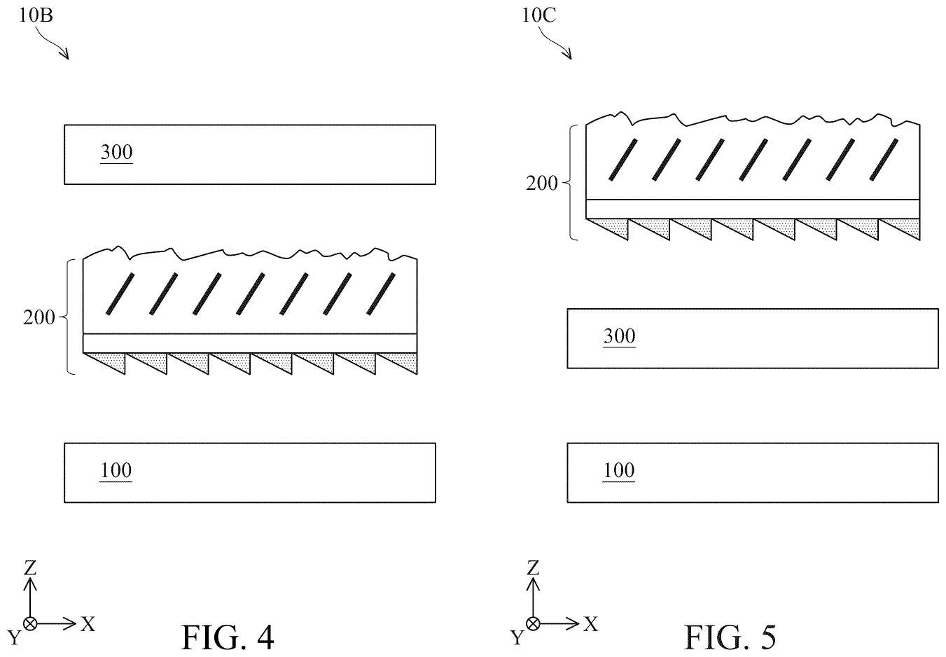

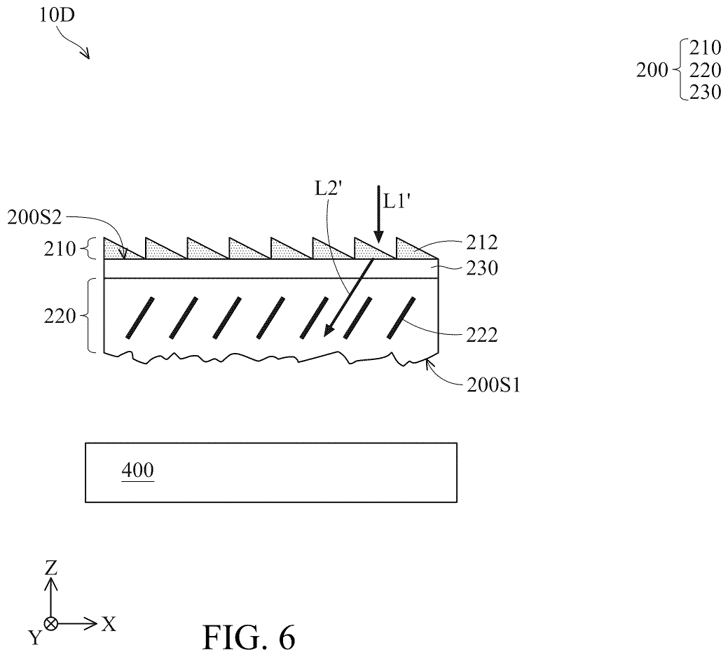

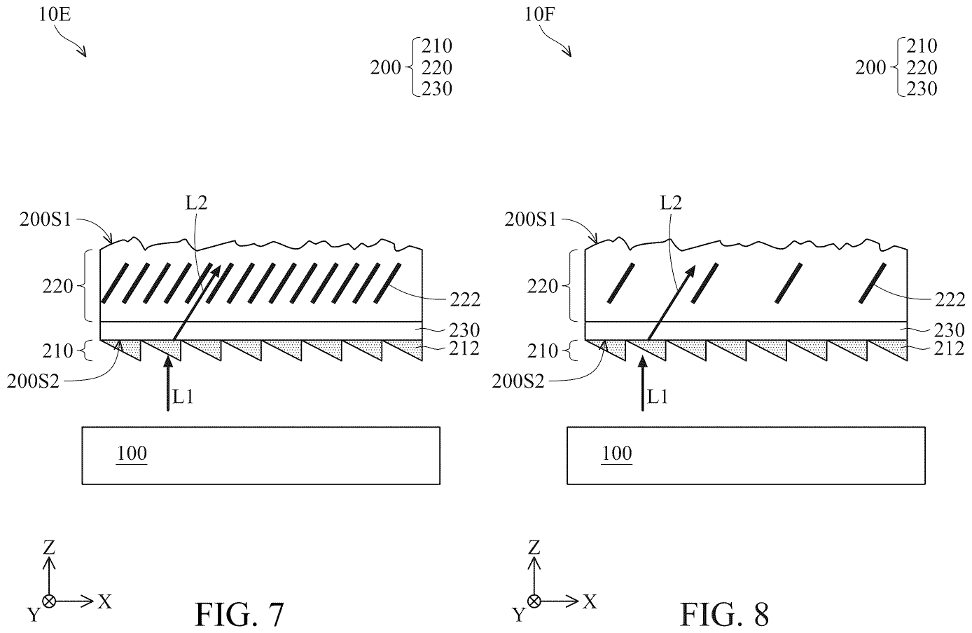

Next, please refer to FIG. 3, which is an optical analysis result of the electronic device in some embodiments of the present disclosure. This optical analysis result can be obtained by measuring with a conoscopic lens, but it is not limited thereto. For example, the optical analysis result can be measured or analyzed using a Conoscope, BM5A, Conometer80U or another suitable instrument, but it is not limited thereto. In FIG. 3, θc=90 degrees, θc=60 degrees, θc=48 degrees, θc=25 degrees, and θc=15 degrees respectively show the brightness (cd/m²) distribution diagram when the electronic device has a structure as shown in FIG. 1A and the angle θc of the barrier structure 220 of the optical film 200 is 90 degrees, 60 degrees, 48 degrees, 25 degrees, and 15 degrees.

As shown in FIG. 3, when the barrier structure 220 of the optical film 200 includes barrier walls 222 that are inclined, the emitted light can be shifted in a specific direction. In addition, the pitch Pb between adjacent barrier walls 222 may also affect the range of the light output viewing angle. Therefore, the desired light output angle can be designed by adjusting the angle θc of the barrier structure 220 or, further, by modifying the pitch Pb, thereby meeting different specification requirements.

Please refer to FIG. 4, which is a cross-sectional diagram of an electronic device 10B in accordance with some other embodiments of the present disclosure. The electronic device 10B is substantially similar to the electronic device 10A shown in FIG. 1A. Compared with the electronic device 10A, the electronic device 10B further includes a display panel 300, and the optical film 200 is disposed between the display panel 300 and the light-emitting structure 100. In this embodiment, the light-emitting structure 100 may serve as a backlight module, and the electronic device 10B may be a non-self-luminous display device, but it is not limited thereto. The display panel 300 may include a liquid-crystal panel, for example, a twisted nematic (TN) type liquid-crystal panel, a super twisted nematic (STN) type liquid-crystal panel, a vertical alignment (VA) type liquid-crystal panel, an in-plane switching (IPS) type liquid-crystal panel, a cholesterol type liquid-crystal panel, a fringe field switching (FFS) type liquid-crystal panel, another suitable liquid-crystal panel or a combination thereof, but it is not limited thereto. In addition, although FIG. 4 only illustrates the aspect in which the optical film 200 is disposed between the display panel 300 and the light-emitting structure 100, the optical film 200 may also be disposed in the light-emitting structure 100 in accordance with domr other embodiments.

Please refer to FIG. 5, which is a cross-sectional diagram of an electronic device 10C in accordance with some other embodiments of the present disclosure. The electronic device 10C is substantially similar to the electronic device 10A shown in FIG. 1A. Compared with the electronic device 10A, the electronic device 10C further includes a display panel 300, and the display panel 300 is disposed between the optical film 200 and the light-emitting structure 100. In this embodiment, the light-emitting structure 100 maysesrve as a backlight module, and the electronic device 10C may be a non-self-luminous display device, but it is not limited thereto.

Next, please refer to FIG. 6, which is a cross-sectional diagram of an electronic device 10D in accordance with some other embodiments of the present disclosure. The electronic device 10D may include a sensing structure 400 and an optical film 200, and the optical film 200 may be disposed on the sensing structure 400. The optical film 200 may include a microstructure layer 210 and a barrier structure 220, and the barrier structure 220 is adjacent to the microstructure layer 210. Moreover, the barrier structure 220 is disposed between the sensing structure 400 and the microstructure layer 210. The optical film 200 may be disposed on the side of the sensing structure 400 for absorbing light. The optical film 200 may be integrated with the sensing structure 400, for example, by a fixing element. The optical film 200 may be in contact with the sensing structure 400, but the present disclosure is not limited thereto.

In this embodiment, the electronic device 10D may serve as a sensing device, but it is not limited thereto. The sensing structure 400 may include an ambient light sensor (ALS), but it is not limited thereto. The sensing structure 400 can receive light at specific angles through the optical film 200. For example, a light L1′ can be adjusted to a light L2′ having a specific optical property (for example, having a specific incident angle or path) through the optical film 200. In detail, the light L1′ can first pass through the microstructure layer 210 and then pass through the barrier structure 220. The microstructure layer 210 may be adjacent to the light incident surface of the electronic device 10D, and the barrier structure 220 is farther away from the light incident surface of the electronic device 10D than the microstructure layer 210.

Referring to FIG. 6, the optical film 200 has a first surface 200S1 adjacent to the sensing structure 400 and a second surface 200S2 away from the sensing structure 400. The microstructure layer 210 may be disposed on the second surface 200S2 of the optical film 200. The first surface 200S1 of the optical film 200 may be roughened by a surface treatment. For example, a coating may be formed on the first surface 200S1, or the first surface 200S1 may be roughened by a laser roughening process, a chemical etching process, a mechanical grinding process, another suitable process or a combination thereof. In some embodiments, the roughness (Ra) of the first surface 200S1 of the optical film 200 may be between 0.1μm and 10 μm (i.e. 0.1 μm≤roughness≤10 μm), for example, 0.5, 1, 1.5, 2, 2.5, 3, 3.5, 4, 4.5, 5, 5.5, 6, 6.5, 7, 7.5, 8, 8.5, 9 or 9.5 μm.

Please refer to FIG. 7, which is a cross-sectional diagram of an electronic device 10E in accordance with some other embodiments of the present disclosure. In some embodiments. The electronic device 10E is substantially similar to the electronic device 10A shown in FIG. 1A. Compared with the electronic device 10A, the plurality of barrier walls 222 of the barrier structure 220 in the electronic device 10E may be disposed corresponding to the prisms 212 of the microstructure layer 210, that is, the barrier walls 222 and the prism 212 may be arranged in a many-to-one manner, but the present disclosure is not limited thereto. For example, two, three or four barrier walls 222 may be disposed corresponding to one prism 212, but the present disclosure is not limited thereto.

Please refer to FIG. 8, which is a cross-sectional diagram of an electronic device 10F in accordance with some other embodiments of the present disclosure. The electronic device 10F is substantially similar to the electronic device 10A shown in FIG. 1A. Compared with the electronic device 10A, one barrier wall 222 of the barrier structure 220 in the electronic device 10F may be arranged corresponding to a plurality of prisms 212 of the microstructure layer 210, that is, the barrier wall 222 and the prisms 212 may be arranged in a one-to-many manner, but the present disclosure is not limited thereto. For example, in some embodiments, one barrier wall 222 may be disposed corresponding to two, three, or four prisms 212, but the present disclosure is not limited thereto.

In addition, in some embodiments (not illustrated), portions of the barrier walls 222 and the prisms 212 of the electronic device may be arranged in a one-to-many manner, while other portions of the barrier walls 222 and the prisms 212 may be be arranged in a many-to-one or one-to-one manner. In some embodiments (not illustrated), the optical film 200 has a first region and a second region, and the density of the barrier walls 222 in the first region is different from the density of the barrier walls 222 in the second region. Furthermore, in some embodiments (not illustrated), the density of the prisms 212 in the first region is different from the density of the prisms 212 in the second region. In some embodiments (not illustrated), the barrier structure 220 may not be provided with the barrier wall 222 in the peripheral region or specific region of the optical film 200. In some embodiments (not illustrated), the microstructure layer 210 may not be provided with the prism 212 in the peripheral region or specific region of the optical film 200.

To summarize the above, the provided electronic device includes an optical film having a specific component configuration that effectively controls the viewing angle, reduces stray light, improves light-emitting efficiency and so on, thereby enhancing the performance of the electronic device.

What is claimed is:

1. An electronic device, comprising:
a light-emitting structure; and
an optical film disposed on the light-emitting structure, the optical film comprising:
a microstructure layer; and
a barrier structure adjacent to the microstructure layer,
wherein the microstructure layer is disposed between the light-emitting structure and the barrier structure.

2. The electronic device of claim 1, wherein the barrier structure comprises a wall, a first angle is formed between an extending direction of the wall and an extending direction of the optical film, and the first angle is greater than 0 degrees and less than or equal to 80 degrees.

3. The electronic device of claim 1, wherein the microstructure layer comprises a prism having a first sidewall and a second sidewall, a second angle is formed between the extending direction of the first sidewall and the extending direction of the optical film, a third angle is formed between the extending direction of the second sidewall and the extending direction of the optical film, and the second angle is different from the third angle.

4. The electronic device of claim 3, wherein the second angle ranges from 10 degrees to 90 degrees.

5. The electronic device of claim 3, wherein the third angle ranges from 10 degrees to 90 degrees.

6. The electronic device as claimed in claim 1, wherein the optical film has a first surface away from the light-emitting structure, and a roughness of the first surface ranges from 0.1 μm to 10 μm.

7. The electronic device as claimed in claim 1, wherein the optical film has a second surface adjacent to the light-emitting structure, and the microstructure layer is disposed on the second surface of the optical film.

8. The electronic device as claimed in claim 1, wherein the microstructure layer is adjacent to a light-emitting surface of the light-emitting structure.

9. The electronic device as claimed in claim 1, wherein the optical film further comprises a light adjustment layer disposed between the microstructure layer and the barrier structure.

10. The electronic device as claimed in claim 1, further comprising:
a display panel, wherein the optical film is disposed between the display panel and the light-emitting structure.

11. The electronic device as claimed in claim 1, further comprising:
a display panel, wherein the display panel is disposed between the optical film and the light-emitting structure.

12. The electronic device as claimed in claim 1, wherein the barrier structure comprises a plurality of barrier walls, and a pitch of the plurality of barrier walls ranges from 10 μm to 100 μm.

13. The electronic device as claimed in claim 1, wherein the microstructure layer comprises a plurality of prisms, and a pitch of the plurality of prisms ranges from 10 μm to 100 μm.

14. The electronic device as claimed in claim 1, wherein the optical film has a first region and a second region, the barrier structure comprises a plurality of barrier walls, and a density of the barrier walls in the first region is different from a density of the barrier walls in the second region.

15. The electronic device as claimed in claim 1, wherein the optical film has a first region and a second region, the microstructure layer comprises a plurality of prisms, and a density of the prisms in the first region is different from a density of the prisms in the second region.

16. An electronic device, comprising:
a sensing structure; and
an optical film disposed on the sensing structure, the optical film comprising:
a microstructure layer; and
a barrier structure adjacent to the microstructure layer,
wherein the barrier structure is disposed between the sensing structure and the microstructure layer.

17. The electronic device as claimed in claim 16, wherein the barrier structure comprises a wall, a first angle is formed between an extending direction of the wall and an extending direction of the optical film, and the first angle being greater than 0 degrees and less than or equal to 80 degrees.

18. The electronic device as claimed in claim 16, wherein the microstructure layer comprises a prism having a first sidewall and a second sidewall, a second angle is formed between the extending direction of the first sidewall and the extending direction of the optical film, a third angle is formed between the extending direction of the second sidewall and the extending direction of the optical film, and the second angle is different from the third angle.

19. The electronic device as claimed in claim 16, wherein the optical film has a first surface adjacent to the sensing structure, and a roughness of the first surface ranges from 0.1 μm to 10 μm.

20. The electronic device as claimed in claim 16, wherein the optical film has a second surface away from the sensing structure, the microstructure layer is disposed on the second surface of the optical film, and the microstructure layer is adjacent to a light-incident surface of the electronic device.
